(19) United States
(12) Patent Application Publication
(10) Pub. No.: US 2023/0164983 A1
(43) Pub. Date: May 25, 2023

(54) METHOD FOR PREPARING SEMICONDUCTOR STRUCTURE, SEMICONDUCTOR STRUCTURE AND SEMICONDUCTOR MEMORY

(71) Applicant: CHANGXIN MEMORY TECHNOLOGIES, INC., Hefei City (CN)

(72) Inventors: Yexiao YU, Hefei (CN); Zhongming LIU, Hefei (CN); Longyang CHEN, Hefei (CN); SHIJIE BAI, Hefei (CN)

(21) Appl. No.: 17/844,209

(22) Filed: Jun. 20, 2022

Related U.S. Application Data
(63) Continuation of application No. PCT/CN2021/137551, filed on Dec. 13, 2021.

(30) Foreign Application Priority Data
Nov. 24, 2021 (CN) 202111403797.6

(51) Int. Cl. H01L 27/108

(52) U.S. Cl. CPC H01L 27/10885

(57) ABSTRACT

A method for preparing a semiconductor structure includes the following operations. A substrate is provided. An active area is included in the substrate. A first dielectric wall and a second dielectric wall extending in a first direction are formed on the substrate. The first dielectric wall and the second dielectric wall are alternately distributed. The first dielectric wall and the second dielectric wall are etched to form a groove extending in a second direction. The grooves are arranged at intervals. In the groove, the height of the remaining first dielectric wall is greater than that of the remaining second dielectric wall. The remaining second dielectric wall in the groove is etched to form first contact holes which are arranged at intervals in the groove. The first contact hole exposes the active area.

### CROSS-REFERENCE TO RELATED APPLICATIONS

The present application is a U.S. continuation application of International Application No. PCT/CN2021/137551, filed on Dec. 13, 2021, which claims priority to Chinese Patent Application No. 202111403797.6, filed on Nov. 24, 2021. International Application No. PCT/CN2021/137551 and Chinese Patent Application No. 202111403797.6 are incorporated herein by reference in their entireties.

### BACKGROUND

With the continuous development of semiconductor technology, an integrated circuit continuously pursues high speed, high integration density and low power consumption. Therefore, the structure size of a semiconductor device in the integrated circuit is also continuously miniaturized.

An existing semiconductor structure is more and more difficult to meet the needs of development, the semiconductor structure needs to constantly innovate, and more novel semiconductor structures are designed.

### SUMMARY

Embodiments of the disclosure provide a method for preparing a semiconductor structure. The method may include the following operations.

A substrate is provided. An active area is included in the substrate.

A first dielectric wall and a second dielectric wall extending in a first direction are formed on the substrate. The first dielectric wall and the second dielectric wall are alternately distributed.

The first dielectric wall and the second dielectric wall are etched to form a groove extending in a second direction. The grooves are arranged at intervals. In the groove, the height of the remaining first dielectric wall is greater than that of the remaining second dielectric wall.

The remaining second dielectric wall in the groove is etched to form first contact holes which are arranged at intervals in the groove. The first contact hole exposes the active area.

The embodiments of the disclosure further provide a semiconductor structure, which is prepared by the preparation method in the above solution.

The embodiments of the disclosure further provide a semiconductor memory, which may include the semiconductor structure in the above solution.

### BRIEF DESCRIPTION OF THE DRAWINGS

FIG. 1 is a flowchart 1 of a method for preparing a semiconductor structure according to embodiments of the disclosure.

FIG. 2A is a schematic diagram 1 of a method for preparing a semiconductor structure according to embodiments of the disclosure.

FIG. 2B is a schematic diagram 2 of a method for preparing a semiconductor structure according to embodiments of the disclosure.

FIG. 3A is a schematic diagram 3 of a method for preparing a semiconductor structure according to embodiments of the disclosure.

FIG. 3B is a schematic diagram 4 of a method for preparing a semiconductor structure according to embodiments of the disclosure.

FIG. 4A is a schematic diagram 5 of a method for preparing a semiconductor structure according to embodiments of the disclosure.

FIG. 4B is a schematic diagram 6 of a method for preparing a semiconductor structure according to embodiments of the disclosure.

FIG. 5 is a flowchart 2 of a method for preparing a semiconductor structure according to embodiments of the disclosure.

FIG. 6A is a schematic diagram 7 of a method for preparing a semiconductor structure according to embodiments of the disclosure.

FIG. 6B is a schematic diagram 8 of a method for preparing a semiconductor structure according to embodiments of the disclosure.

FIG. 7A is a schematic diagram 9 of a method for preparing a semiconductor structure according to embodiments of the disclosure.

FIG. 7B is a schematic diagram 10 of a method for preparing a semiconductor structure according to embodiments of the disclosure.

FIG. 8A is a schematic diagram 11 of a method for preparing a semiconductor structure according to embodiments of the disclosure.

FIG. 8B is a schematic diagram 12 of a method for preparing a semiconductor structure according to embodiments of the disclosure.

FIG. 9A is a schematic diagram 13 of a method for preparing a semiconductor structure according to embodiments of the disclosure.

FIG. 9B is a schematic diagram 14 of a method for preparing a semiconductor structure according to embodiments of the disclosure.

FIG. 10 is a flowchart 3 of a method for preparing a semiconductor structure according to embodiments of the disclosure.

FIG. 11A is a schematic diagram 15 of a method for preparing a semiconductor structure according to embodiments of the disclosure.

FIG. 11B is a schematic diagram 16 of a method for preparing a semiconductor structure according to embodiments of the disclosure.

FIG. 12A is a schematic diagram 17 of a method for preparing a semiconductor structure according to embodiments of the disclosure.

FIG. 12B is a schematic diagram 18 of a method for preparing a semiconductor structure according to embodiments of the disclosure.

FIG. 13A is a schematic diagram 19 of a method for preparing a semiconductor structure according to embodiments of the disclosure.

FIG. 13B is a schematic diagram 20 of a method for preparing a semiconductor structure according to embodiments of the disclosure.

FIG. 14A is a schematic diagram 21 of a method for preparing a semiconductor structure according to embodiments of the disclosure.

FIG. 14B is a schematic diagram 22 of a method for preparing a semiconductor structure according to embodiments of the disclosure.

FIG. 15A is a schematic diagram 23 of a method for preparing a semiconductor structure according to embodiments of the disclosure.

FIG. 15B is a schematic diagram 24 of a method for preparing a semiconductor structure according to embodiments of the disclosure.

FIG. 16A is a schematic diagram 25 of a method for preparing a semiconductor structure according to embodiments of the disclosure.

FIG. 16B is a schematic diagram 26 of a method for preparing a semiconductor structure according to embodiments of the disclosure.

FIG. 17A is a schematic diagram 27 of a method for preparing a semiconductor structure according to embodiments of the disclosure.

FIG. 17B is a schematic diagram 28 of a method for preparing a semiconductor structure according to embodiments of the disclosure.

FIG. 18A is a schematic diagram 29 of a method for preparing a semiconductor structure according to embodiments of the disclosure.

FIG. 18B is a schematic diagram 31 of a method for preparing a semiconductor structure according to embodiments of the disclosure.

FIG. 19 is a flowchart 4 of a method for preparing a semiconductor structure according to embodiments of the disclosure.

FIG. 20A is a schematic diagram 32 of a method for preparing a semiconductor structure according to embodiments of the disclosure.

FIG. 20B is a schematic diagram 33 of a method for preparing a semiconductor structure according to embodiments of the disclosure.

FIG. 21A is a schematic diagram 34 of a method for preparing a semiconductor structure according to embodiments of the disclosure.

FIG. 21B is a schematic diagram 35 of a method for preparing a semiconductor structure according to embodiments of the disclosure.

FIG. 22 is a flowchart 5 of a method for preparing a semiconductor structure according to embodiments of the disclosure.

FIG. 23 is a schematic diagram 36 of a method for preparing a semiconductor structure according to embodiments of the disclosure.

FIG. 24A is a schematic diagram 37 of a method for preparing a semiconductor structure according to embodiments of the disclosure.

FIG. 24B is a schematic diagram 38 of a method for preparing a semiconductor structure according to embodiments of the disclosure.

FIG. 25 is a flowchart 6 of a method for preparing a semiconductor structure according to embodiments of the disclosure.

FIG. 26 is a schematic diagram 39 of a method for preparing a semiconductor structure according to embodiments of the disclosure.

FIG. 27 is a schematic diagram 40 of a method for preparing a semiconductor structure according to embodiments of the disclosure.

FIG. 28A is a schematic diagram 41 of a method for preparing a semiconductor structure according to embodiments of the disclosure.

FIG. 28B is a schematic diagram 42 of a method for preparing a semiconductor structure according to embodiments of the disclosure.

FIG. 29A is a schematic diagram 43 of a method for preparing a semiconductor structure according to an embodiments of the disclosure.

FIG. 29B is a schematic diagram 44 of a method for preparing a semiconductor structure according to embodiments of the disclosure.

FIG. 30 is a flowchart 7 of a method for preparing a semiconductor structure according to embodiments of the disclosure.

FIG. 31A is a schematic diagram 45 of a method for preparing a semiconductor structure according to embodiments of the disclosure.

FIG. 31B is a schematic diagram 46 of a method for preparing a semiconductor structure according to embodiments of the disclosure.

FIG. 32A is a schematic diagram 47 of a method for preparing a semiconductor structure according to embodiments of the disclosure.

FIG. 32B is a schematic diagram 48 of a method for preparing a semiconductor structure according to embodiments of the disclosure.

FIG. 33 is a schematic diagram of a structure of a semiconductor memory according to embodiments of the disclosure.

### DETAILED DESCRIPTION

The disclosure relates to the field of semiconductor technology, and in particular to a method for preparing a semiconductor structure, a semiconductor structure and a semiconductor memory.

For making the objectives, technical solutions, and advantages of the present application clearer, the technical solutions of the disclosure will further be described below in combination with the drawings and the embodiments in detail. The described embodiments should not be considered as limits to the disclosure. All other embodiments obtained by those of ordinary skill in the art without creative work shall fall within the scope of protection of the disclosure.

“Some embodiments” involved in the following descriptions describes a subset of all possible embodiments. However, it can be understood that “some embodiments” may be the same subset or different subsets of all the possible embodiments, and may be combined without conflicts.

When the similar descriptions of “first/second” appear in the context, the following descriptions will apply. Terms “first/second/third” involved in the following descriptions are only for distinguishing similar objects and do not represent a specific sequence of the objects. It can be understood that “first/second/third” may be interchanged to specific sequences or orders if allowed to implement the embodiments of the disclosure described herein in sequences except the illustrated or described ones.

Unless otherwise defined, all technological and scientific terms used in the disclosure have meanings the same as those usually understood by those skilled in the art of the disclosure. The terms used in the disclosure are only adopted to describe the embodiments of the disclosure and not intended to limit the disclosure.

A Dynamic Random Access Memory (DRAM) is a semiconductor element often used in electronic devices such as computers, and is composed of a plurality of storage units. Each storage unit usually includes a capacitor and a transistor. A gate of the transistor is electrically connected with a word line, a source is electrically connected with a bit line, and a drain is electrically connected with the capacitor. A voltage signal on the word line can control the transistor to be turned on or turned off to further read data information stored in the capacitor through the bit line or write data information in the capacitor.

The development of the DRAM pursues performances such as high speed, high integration density and low power consumption. With the miniaturization of the structure size of a semiconductor device, especially in the process of manufacturing the DRAM with key size less than 15 nm, the technical barriers encountered by the existing structure are increasingly apparent. Therefore, developing more novel structures on the basis of the existing structure is a favorable means to break the existing technical barriers.

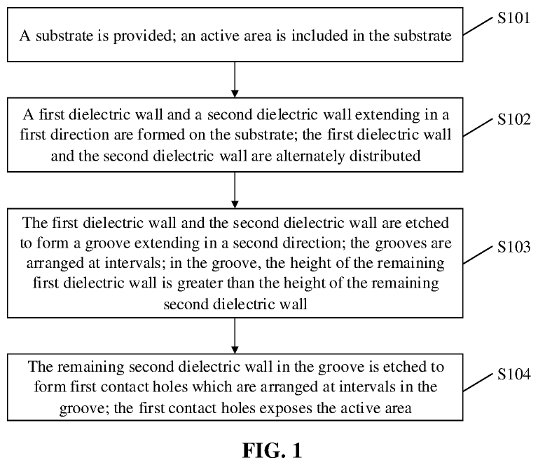

FIG. 1 is an optional flowchart of a method for preparing a semiconductor structure according to embodiments of the disclosure. Details will be described with reference to the steps shown in FIG. 1.

At S101, a substrate is provided. The substrate includes an active area.

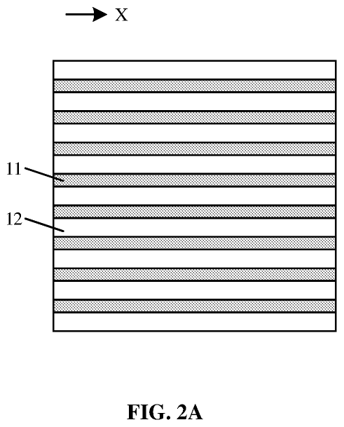

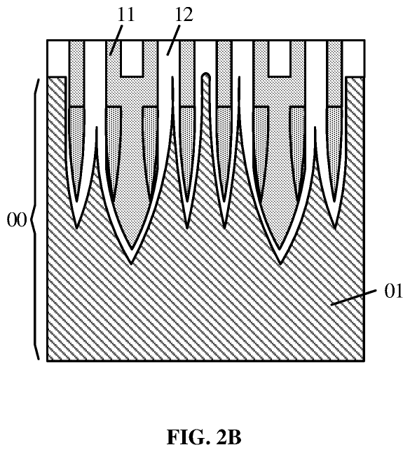

In the embodiments of the disclosure, FIG. 2B is a side sectional view. As shown in FIG. 2B, the substrate 00 may be a semiconductor substrate, such as a silicon substrate, a germanium substrate, a silicon germanium substrate, a germanium arsenic substrate, a Silicon On Insulator (SOI) substrate, a Germanium On Insulator (GOI) substrate. The substrate 00 may be doped or undoped. Exemplarily, the substrate 00 may be an N-type substrate or a P-type substrate. The substrate 00 includes the active area 01.

It is to be noted that a substrate is a clean single crystal sheet for processing a semiconductor and has a specific crystal plane and appropriate electrical, optical, and mechanical properties. A semiconductor structure is processed on a substrate.

At S102, a first dielectric wall and a second dielectric wall extending in a first direction are formed on the substrate. The first dielectric wall and the second dielectric wall are alternately distributed.

In the embodiments according to the semiconductor device of the disclosure, the first dielectric wall and the second dielectric wall may be formed on the substrate. FIG. 2A and FIG. 2B are top and side sectional views respectively. As shown in FIG. 2A and FIG. 2B, the first dielectric wall 11 and the second dielectric wall 12 extending in the first direction X are formed on the substrate 00. The first dielectric wall 11 and the second dielectric wall 12 are alternately distributed.

In the embodiments of the disclosure, the material of the first dielectric wall may be silicon nitride (SiN) and the material of the second dielectric wall may be silicon oxide (SiO₂).

At S103, the first dielectric wall and the second dielectric wall are etched to form a groove extending in a second direction. Grooves are arranged at intervals. In the groove, the height of the remaining first dielectric wall is greater than the height of the remaining second dielectric wall.

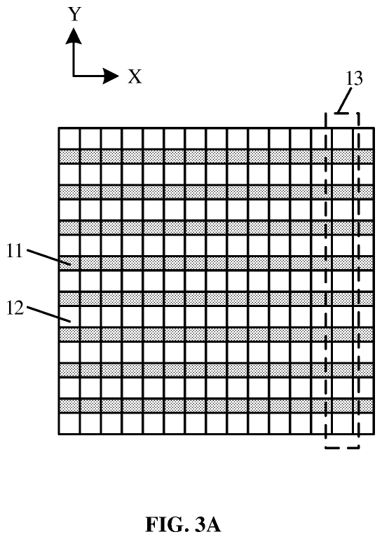

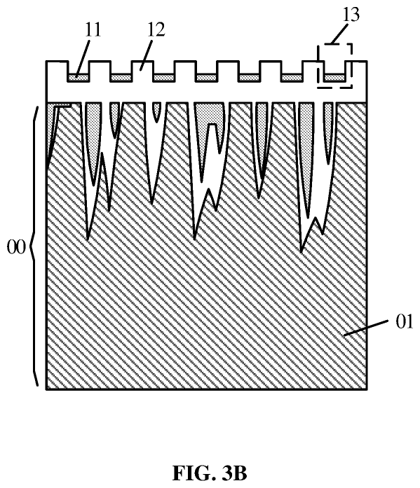

In the embodiments according to the semiconductor device of the disclosure, the first dielectric wall and the second dielectric wall may be etched to form the groove extending in the second direction. FIG. 3A and FIG. 3B are top and front sectional views respectively. As shown in FIG. 3A and FIG. 3B, the first dielectric wall 11 and the second dielectric wall 12 are etched to form the groove 13. The grooves 13 extend in the second direction Y and are arranged at intervals. In the groove 13, the height of the remaining first dielectric wall 11 is greater than the height of the remaining second dielectric wall 12. Therefore, in FIG. 3B, the remaining first dielectric wall 11 in the groove 13 shields the remaining second dielectric wall 12. In this way, a square hole as shown in FIG. 3A is formed at the position of the remaining second dielectric wall in the groove 13.

In the embodiments of the disclosure, when a ratio of the etching rate of the material of the first dielectric wall to the etching rate of the material of the second dielectric wall is 1:4, the height of the remaining first dielectric wall 11 in the groove 13 accounts for three fourths of the depth of the groove 13.

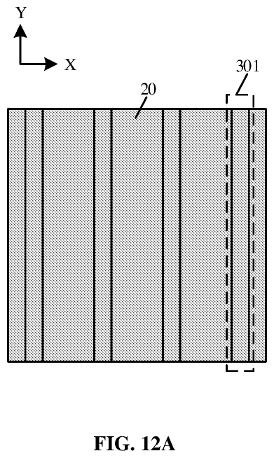

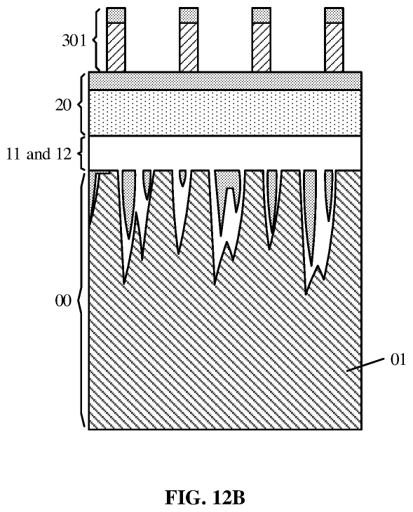

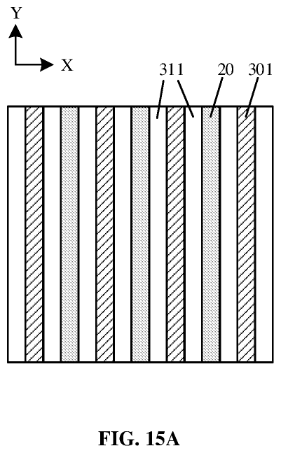

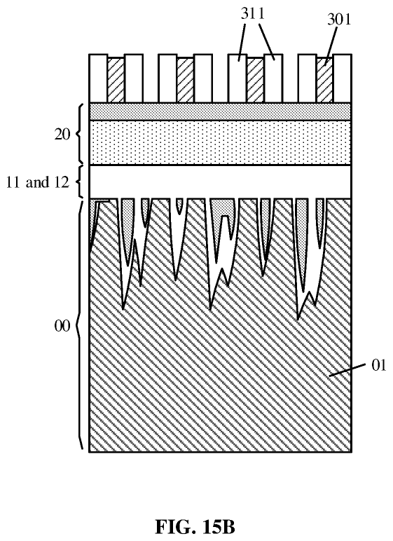

In the embodiments of the disclosure, the semiconductor device may first form a widely spaced mandrels through a photolithography process, as shown in FIG. 12A and FIG. 12B, the mandrels 301 extends in the second direction Y. Then, side walls may be formed on both sides of the mandrels, as shown in FIG. 15A and FIG. 15B, the side walls 311 cover both sides of the mandrels 301, and the side walls 311 also extend in the second direction Y. Finally, the groove 13 is etched by taking the side walls as a mask. Due to the fact that the side walls 311 are formed in the spacer regions of the mandrels 301, the distance between the side walls is smaller than the distance between the mandrels 301. Therefore, the size of the groove 13 formed by etching is smaller than that of the mandrels 301, that is, a groove with smaller size is formed by utilizing a photomask with larger size.

At S104, the remaining second dielectric wall in the groove is etched to form first contact holes which are arranged at intervals in the groove. The first contact hole exposes the active area.

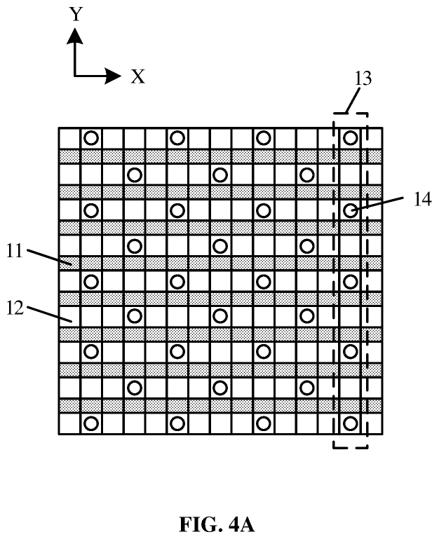

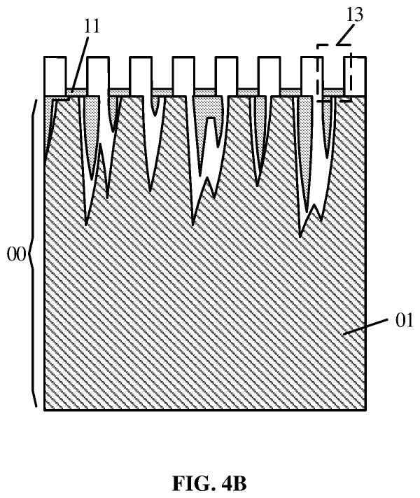

In the embodiments according to the semiconductor device of the disclosure, the remaining second dielectric wall in the groove may be etched to form the first contact holes which are arranged at intervals in the groove. The first contact hole penetrates through the remaining second dielectric wall, so that the active area is exposed. FIG. 4A and FIG. 4B are top and front sectional views respectively. As shown in FIG. 4A and FIG. 4B, the remaining second dielectric wall 12 in the groove 13 is etched to form the first contact holes 14. The first contact holes 14 are arranged at intervals and expose the active area 01.

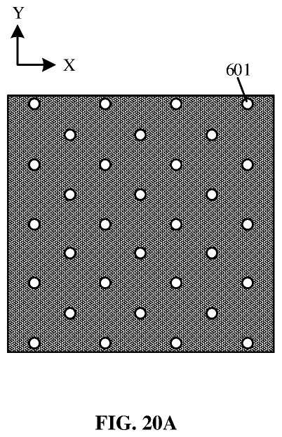

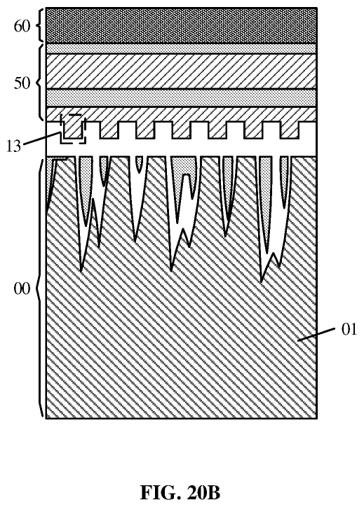

In the embodiments according to the semiconductor device of the disclosure, a third blocking layer may be deposited in the groove and then a second mask is formed on the third blocking layer through a photolithography process. FIG. 20A and FIG. 20B are top and front sectional views respectively. As shown in FIG. 20A and FIG. 20B, the third blocking layer 50 is deposited on the groove 13 to cover the groove 13. The second mask 60 is formed on the third blocking layer 50, and the second mask 60 includes concave holes (namely second etching patterns 601). The concave holes are arranged at intervals. The concave hole needs to be aligned with the square hole of the remaining second dielectric wall 12 in the groove 13, so that the first contact hole 14 can be formed in the position of the remaining second dielectric wall 12, as shown in FIG. 4A. Then, according to the semiconductor device, etching may be performed at least once along the second etching pattern 601 to remove the third blocking layer 50, and the remaining second dielectric wall 12 in the groove 13 is etched to form the first contact hole 14 shown in FIG. 4A.

It is to be understood that in the embodiments of the disclosure, the first dielectric wall and the second dielectric wall which extend in the first direction and are alternately distributed are formed on the substrate, and then the first dielectric wall and the second dielectric wall are etched to form the groove extending in the second direction. By utilizing different materials of the first dielectric wall and the second dielectric wall and selecting an appropriate etching rate ratio, the height of the remaining first dielectric wall in the groove is greater than the height of the remaining second dielectric wall, the square hole is formed in the remaining second dielectric wall which provide a position for arrangement of the first contact hole.

Then, the remaining second dielectric wall in the groove is etched to form the first contact holes which are arranged at intervals by aligning with the square holes. In this way, the groove provides an embedded area for metal wiring, the first contact hole provides a contact point of the metal wiring and the active area, and only two times of photomasking are needed for two times of etching. Therefore, a novel semiconductor structure capable of performing metal wiring is formed with less times of photomasking, thereby providing a new choice for the semiconductor technology.

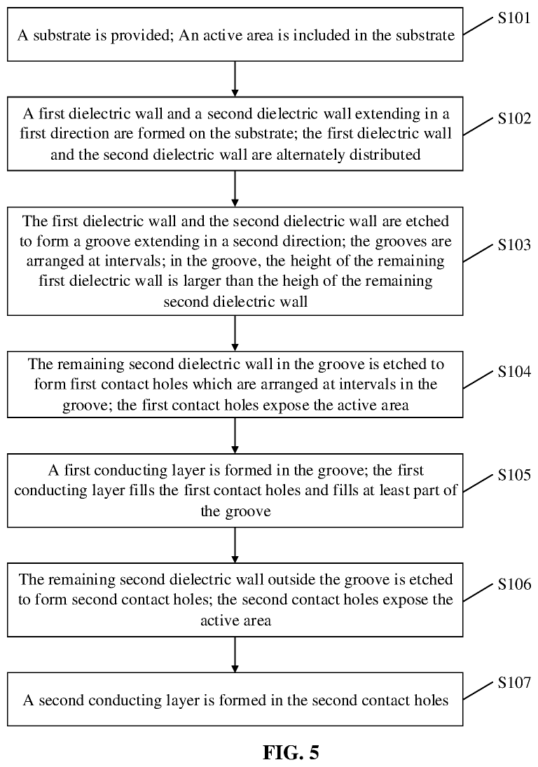

In some embodiments of the disclosure, S105-S107 shown in FIG. 5 are further included after S104 shown in FIG. 1, which will be explained with reference to each step.

At S105, a first conducting layer is formed in the groove. The first conducting layer fills the first contact hole and fills at least part of the groove.

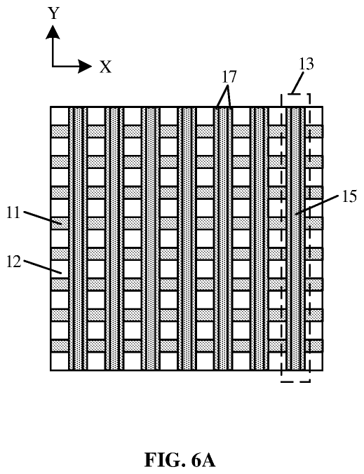

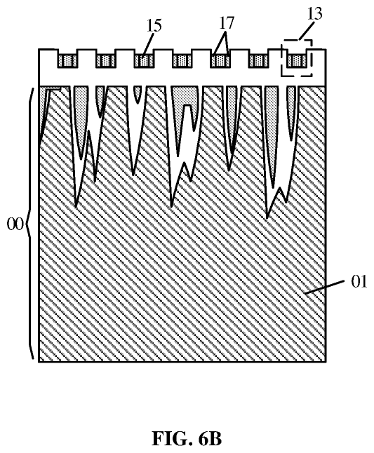

In the embodiments according to the semiconductor device of the disclosure, after forming the first contact hole in the groove, the first conducting layer may be formed in the groove. The first conducting layer fills the first contact hole and fills at least part of the groove. FIG. 6A and FIG. 6B are top and front sectional views respectively. As shown in FIG. 6A and FIG. 6B, the first conducting layer 15 is formed in the groove 13, and the first conducting layer 15 fills part of the first contact hole and the groove 13, that is, the thickness of the first conducting layer 15 is smaller than the depth of the groove 13. Meanwhile, according to the semiconductor device, a second isolation layer 17 with the same material as the first dielectric wall 11 may also be formed on both sides of the first conducting layer 15, and the second isolation layer 17 isolates the first conducting layer 15 from others.

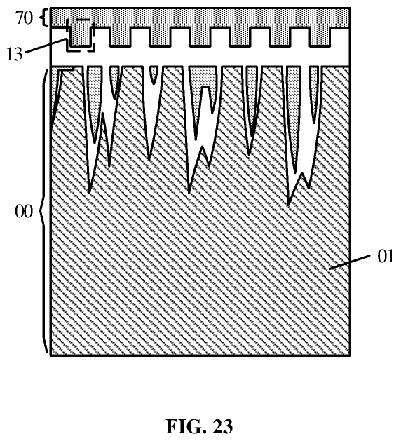

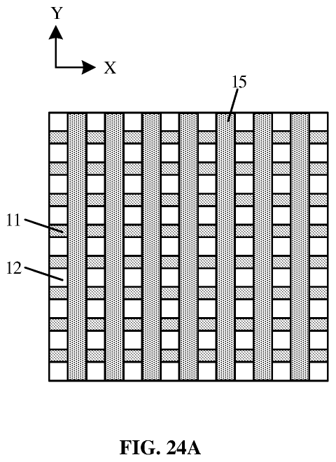

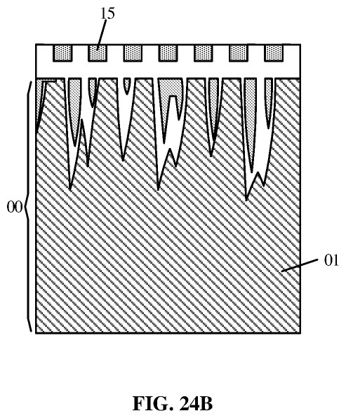

In the embodiments of the disclosure, if the metal material is in direct contact with the active area, it will diffuse into the active area and destroy the electrical characteristics of the active area. Therefore, according to the semiconductor device, a metal isolation layer, such as TiN, may be deposited in the first contact hole to prevent the metal material diffusing into the active area. Then, a metal layer is deposited, as shown in FIG. 23, the metal layer 70 covers the metal isolation layer and fills the first contact holes 14 (not shown due to shielding) and the groove 13. The material of the metal layer 70 may be tungsten (W) or copper (Cu). Then, the metal layer 70 is ground to the top of the groove 13, that is, the metal layer 70 is ground by a Damascus process to form the first conducting layer 15 shown in FIG. 24A and FIG. 24B.

In the embodiments of the disclosure, the first conducting layer 15 may be configured to a bit line structure.

At S106, the remaining second dielectric wall outside the groove is etched to form a second contact hole. The second contact hole exposes the active area.

In the embodiments according to the semiconductor device of the disclosure, after forming the first conducting layer, the remaining second dielectric wall outside the groove may be etched to form the second contact hole, and the second contact hole exposes the active area.

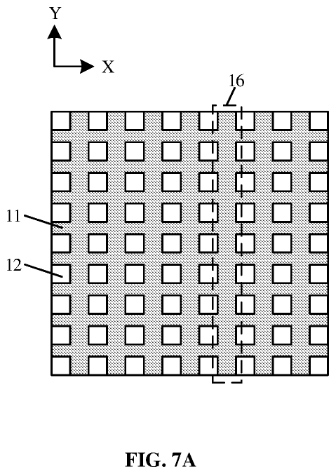

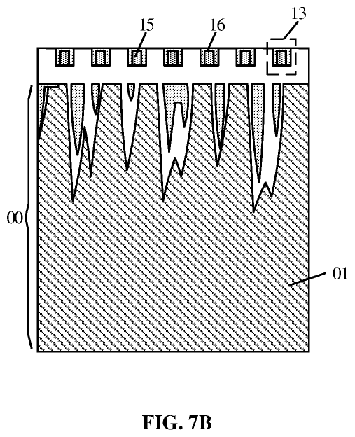

In the embodiments according to the semiconductor device of the disclosure, a first isolation layer may be first formed on the first conducting layer. FIG. 7A and FIG. 7B are top and front sectional views respectively. As shown in FIG. 7A and FIG. 7B, the first isolation layer 16 is formed on the first conducting layer 15, and the first isolation layer 16 covers the first conducting layer 15 and fills the rest of the groove 13. The materials of the first isolation layer 16 and the first dielectric wall 11 are the same.

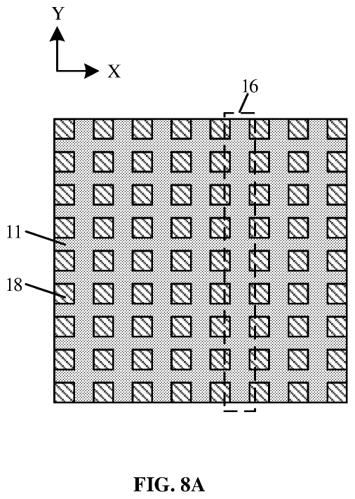

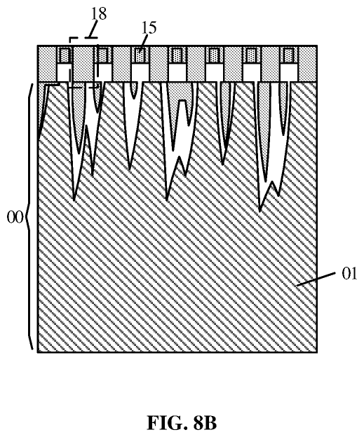

Then, according to the semiconductor device, the remaining second dielectric wall outside the groove may be etched by taking the remaining first dielectric wall outside the groove and the first isolation layer as a mask to form the second contact hole. Due to the fact that the materials of the first isolation layer 16 and the first dielectric wall 11 are the same, etching may be performed with a higher etching selection ratio of the material of the second dielectric wall 12 than the material of the first isolation layer 16 and the first dielectric wall 11. For example, when the material of the first isolation layer 16 and the first dielectric wall 11 is silicon nitride and the material of the second dielectric wall 12 is silicon oxide, etching is performed with a higher etching selection ratio of silicon oxide than that of silicon nitride. In this way, only the remaining second dielectric wall 12 outside the groove 13 is etched, and the first isolation layer 16 and the first dielectric wall 11 are retained. FIG. 8A and FIG. 8B are top and front sectional views respectively. As shown in FIG. 8A and FIG. 8B, the remaining second dielectric wall 12 outside the groove 13 is etched to form the second contact hole 18. The second contact hole exposes the active area 01.

At S107, a second conducting layer is formed in the second contact hole.

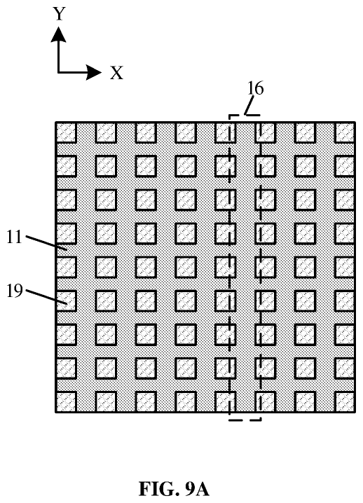

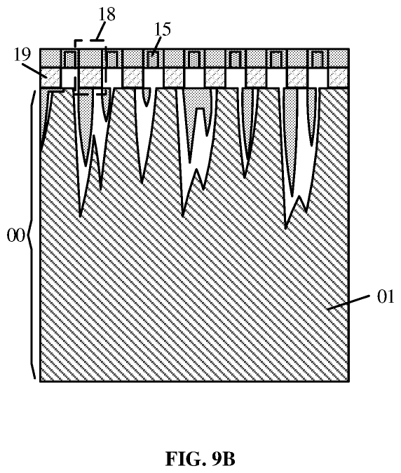

In the embodiments according to the semiconductor device of the disclosure, after forming the second contact hole, the second conducting layer may be formed in the second contact hole. FIG. 9A and FIG. 9B are top and front sectional views respectively. As shown in FIG. 9A and FIG. 9B, the second conducting layer 19 is formed in the second contact hole 18. The second conducting layer 19 fills part of the second contact hole 18 and is in contact with the active area 01.

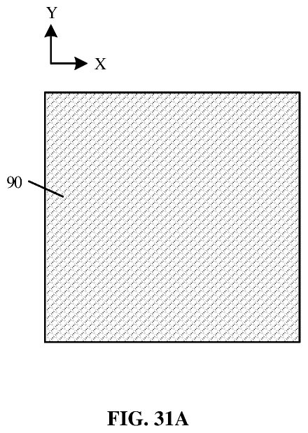

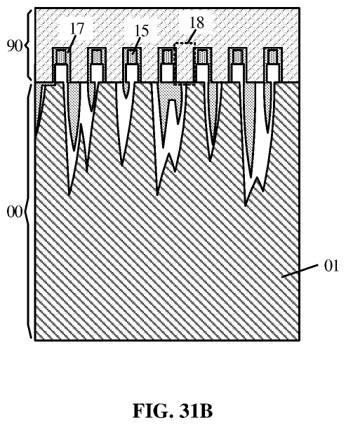

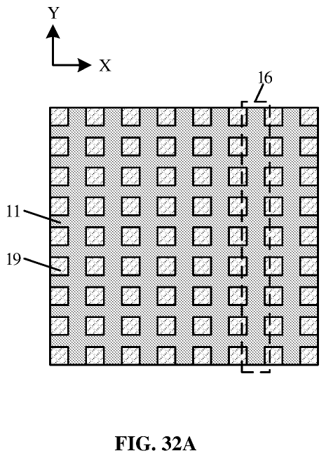

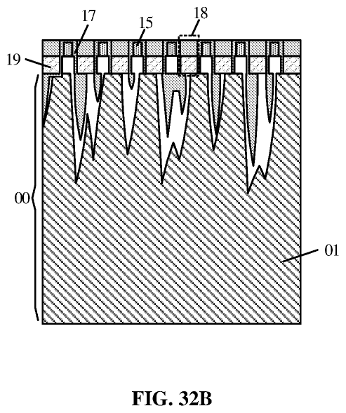

In the embodiments according to the semiconductor device of the disclosure, the second isolation layer may be formed in the second contact hole. FIG. 31B is a front sectional view. As shown in FIG. 31B, the second isolation layer 17 covers the sides of the first conducting layer 15. Then, a conducting medium may be deposited. The material of the conducting medium may be polycrystalline silicon. FIG. 31A and FIG. 31B are top and front sectional views respectively. As shown in FIG. 31A and FIG. 31B, the conducting medium 90 fills the second contact hole 18 and covers the first conducting layer 15, and the second isolation layer 17 isolates the conducting medium 90 from the first conducting layer 15. Then, the conducting medium 90 may be etched with a high selection ratio, that is, the etching rate of the conducting medium 90 is higher than that of other materials. Etching is performed until the height of the conducting medium 90 is lower than the top of the second contact hole 18, thereby exposing the remaining first dielectric wall 11 outside the groove and the first isolation layer 16, as shown in FIG. 32A. In this way, the remaining conducting medium 90 forms the second conducting layer 19. The second isolation layer 17 isolates the first conducting layer 15 from the second conducting layer 19.

It is to be understood that the first conducting layer is formed in the groove and is in contact with the active area through the first contact hole. Meanwhile, the remaining second dielectric wall outside the groove is taken as the mask, the second contact hole is formed in the corresponding position through etching, and the second conducting layer is filled into the second contact hole. In this way, the second contact hole is etched by utilizing the pattern of the semiconductor structure without a photomask, thereby achieving self-alignment.

Meanwhile, the first conducting layer is formed by filling the groove, the second conducting layer is formed by filling the second contact hole, and the first conducting layer and the second conducting layer are both of an embedded structure, so that the height of the semiconductor structure is reduced, and the integration density in the vertical direction is improved.

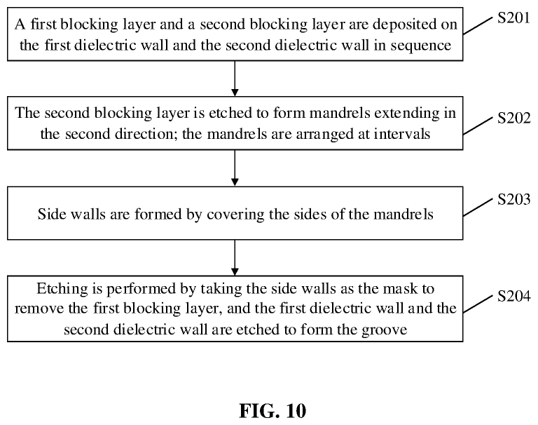

In some embodiments of the disclosure, S103 shown in FIG. 1 may be implemented through S201 to S204 shown in FIG. 10, which will be explained with reference to each step.

At S201, a first blocking layer and a second blocking layer are deposited on the first dielectric wall and the second dielectric wall in sequence.

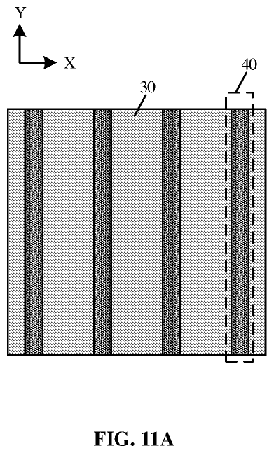

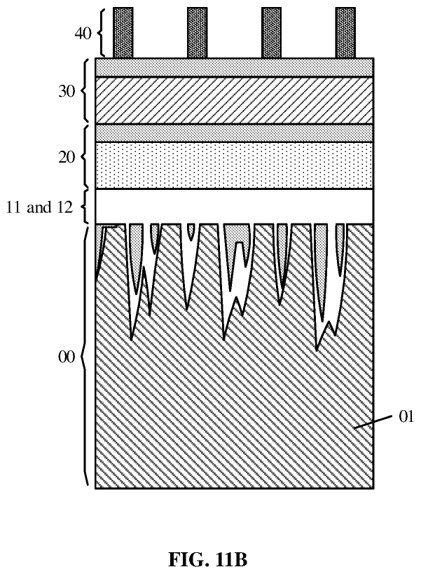

In the embodiments according to the semiconductor device of the disclosure, the first blocking layer and the second blocking layer may be deposited on the first dielectric wall and the second dielectric wall in sequence. It is to be noted that the blocking layer is configured to form a downward transfer pattern as required and protect areas that do not need to be etched during etching. FIG. 11A and FIG. 11B are top and front sectional views respectively. As shown in FIG. 11A and FIG. 11B, the first blocking layer 20 and the second blocking layer 30 are deposited on the first dielectric wall 11 and the second dielectric wall 12 in sequence (due to the shielding relationship, the alternating structure of the first dielectric wall 11 and the second dielectric wall 12 is not shown in FIG. 11B). The materials of the first blocking layer 20 and the second blocking layer 30 may include: SiON (silicon oxynitride) and Spin-on Hardmasks (SOH).

At S202, the second blocking layer is etched to form mandrels extending in the second direction. The mandrels are arranged at intervals.

In the embodiments according to the semiconductor device of the disclosure, the second blocking layer may be etched to form the mandrels extending in the second direction. The mandrels are arranged at intervals.

In the embodiments according to the semiconductor device of the disclosure, as shown in FIG. 11A and FIG. 11B, m a first mask 40 may be formed on the second blocking layer 30 through the photolithography process, and the shape of the first mask 40 is characterized as a first etching pattern extending in the second direction Y. Then, the second blocking layer 30 may be etched along the first etching pattern to form the mandrels 301 shown in FIG. 12A and FIG. 12B. The mandrels 301 extend in the second direction Y and are arranged at intervals.

At S203, side walls are formed by covering side faces of the mandrels.

In the embodiments according to the semiconductor device of the disclosure, side faces of the mandrels to form the side walls.

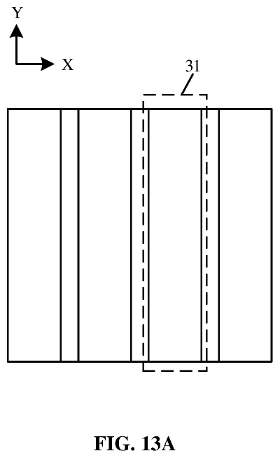

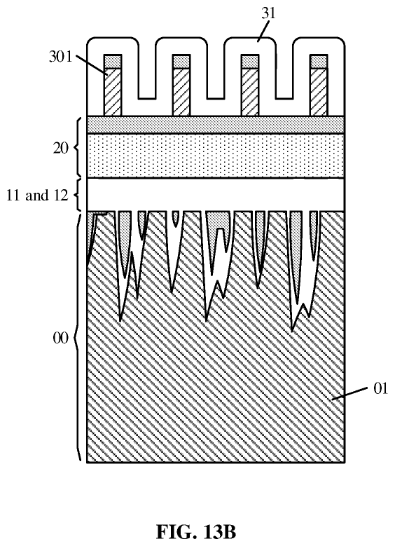

In the embodiments according to the semiconductor device of the disclosure, as shown in FIG. 13A and FIG. 13B, a hard mask layer 31 may be deposited by an Atomic Layer Deposition (ALD) process to cover the first blocking layer 20 and the mandrels 301.

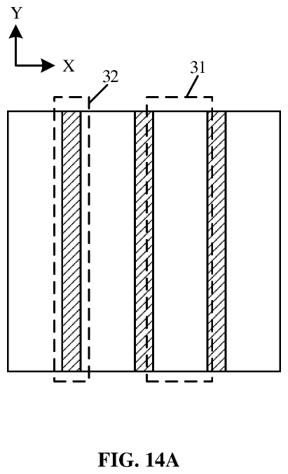

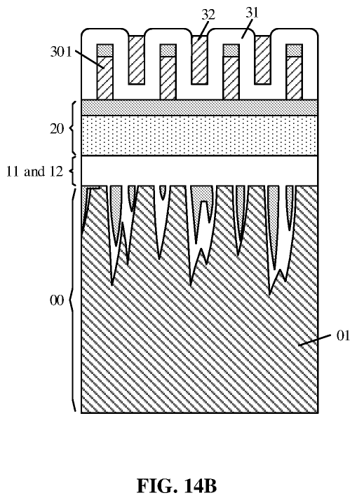

Then, as shown in FIG. 14A and FIG. 14B, a gap between the hard mask layers 31 may be filled with a third dielectric layer 32. The third dielectric layer 32 acts as a blocking layer in subsequent etching.

Then, the hard mask layer 31 may be etched back. The top of the hard mask layer 31 is removed until the mandrels 301 is exposed, and the side of the hard mask layer 31 is retained as the side walls 311, as shown in FIG. 15A and FIG. 15B. The side walls 311 also extend in the second direction Y.

At S204, etching is performed by taking the side walls as the mask. The first blocking layer is removed, and the first dielectric wall and the second dielectric wall are etched to form the groove.

In the embodiments according to the semiconductor device of the disclosure, etching may be performed by taking side wall as the mask. The first blocking layer is removed, and the first dielectric wall and the second dielectric wall are etched to form the groove extending in the second direction.

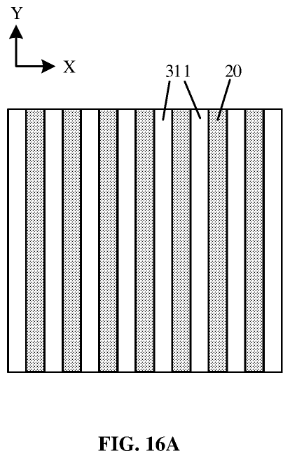

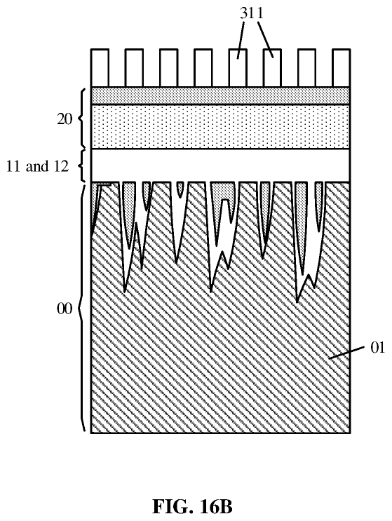

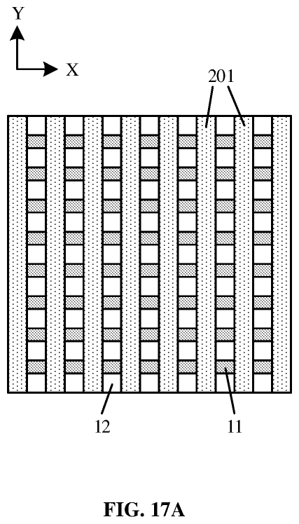

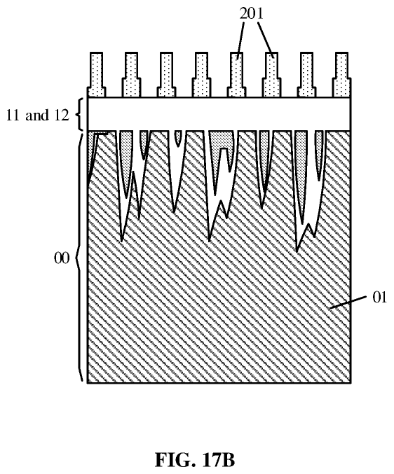

In the embodiments of the disclosure, referring to FIG. 15A and FIG. 15B, the mandrel 301 remains between the side walls 311. Etching may be performed with a high selection etching rate to remove the remaining mandrel 301 between the side walls 311. The high selection ratio means that the etching rate of the material of the mandrels 301 is much higher than that of other materials. The resulted structure is shown in FIG. 16A and FIG. 16B. Then, combined with FIG. 16B and FIG. 17B, the first blocking layer 20 may be etched by taking the side walls 311 as a mask to form a first intermediate structure 201 shown in FIG. 17B, and expose the first dielectric wall 11 and the second dielectric wall 12. As shown in FIG. 17A, the first intermediate structure 201 also extends in the second direction Y as the side walls 311, and the first dielectric wall 11 and the second dielectric wall 12 are exposed at the gap of the first intermediate structures 201.

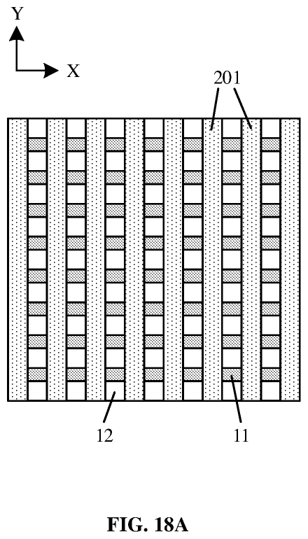

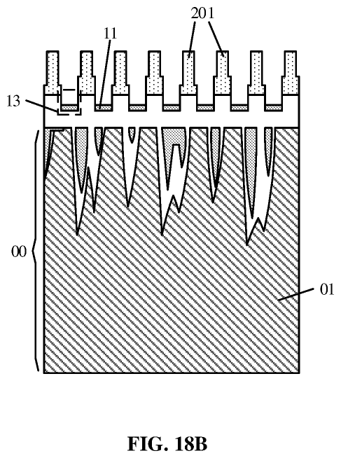

Then, combined with FIG. 17B and FIG. 18B, the first dielectric wall 11 and the second dielectric wall 12 may be etched according to an etching rate ratio by taking the first intermediate structure 201 as a mask. The etching rate ratio may be a ratio of the etching rate of the material of the first dielectric wall to that of the material of the second dielectric wall, which is 1:4. In this way, the structure shown in FIG. 18B may be obtained. At the gap of the first intermediate structures 201, the first dielectric wall 11 and the second dielectric wall 12 are etched to form the groove 13. In the groove 13, the height of the remaining first dielectric wall 11 is greater than that of the remaining second dielectric wall 12, that is, in FIG. 18B, the remaining first dielectric wall 11 in the groove 13 shields the remaining second dielectric wall 12.

Then, the remaining first intermediate structure 201 may be removed to obtain the structure shown in FIG. 3A and FIG. 3B. When the etching rate ratio of the material of the first dielectric wall to that of the material of the second dielectric wall is 1:4, the height of the remaining first dielectric wall 11 in the groove 13 accounts for three fourths of the depth of the groove 13.

It is to be understood that in the embodiments according to the semiconductor device of the disclosure, after depositing the first blocking layer 20 and the second blocking layer 30, the first mask 40 is formed through the photolithography process, and etching is performed along the first mask 40 to form the mandrel 301. Then, side walls 311 are formed by covering the side faces of the mandrel 301. Finally, the groove 13 is etched by taking the side walls 311 as the mask. Due to the fact that the side walls 311 are formed in the spacer regions of the mandrels 301, the distance between the side walls is smaller than that between the mandrels 301. Therefore, the width of the groove 13 formed by taking the side wall 311 as the mask is also smaller than the distance between the mandrels 301. In this way, even if a photolithography process limits the key size that may be achieved, the groove 13 with smaller key size can be formed with the help of the mandrel 301, which expands the process size limit that may be achieved by the semiconductor device.

In some embodiments of the disclosure, S202 shown in FIG. 10 may be implemented through S2021 to S2022, which will be explained with reference to each operation.

At S2021, the first mask is formed on the second blocking layer. The first mask includes the first etching pattern extending in the second direction.

In the embodiments according to the semiconductor device of the disclosure, the first mask may be formed on the second blocking layer. The first mask may be obtained through a photolithography process. FIG. 11A and FIG. 11B illustrate the first mask and are top and front sectional views respectively. As shown in FIG. 11A and FIG. 11B, the first mask 40 is formed on the second blocking layer 30, and the first etching pattern of the first mask 40 extends in the second direction Y.

At S2022, the second blocking layer is etched along the first etching pattern to form the mandrel extending in the second direction.

In the embodiments according to the semiconductor device of the disclosure, after forming the first mask 40, the second blocking layer 30 may be etched along the first etching pattern to form the mandrel 301 shown in FIG. 12A and FIG. 12B. The mandrel 301 also extends in the second direction Y.

In some embodiments of the disclosure, S203 shown in FIG. 10 may be implemented through S2031 to S2032, which will be explained with reference to each operation.

At S2031, the hard mask layer is deposited. The hard mask layer covers the first blocking layer and the mandrel.

In the embodiments according to the semiconductor device of the disclosure, as shown in FIG. 13A and FIG. 13B, the hard mask layer 31 is deposited by adopting the ALD process to cover the first blocking layer 20 and the mandrel 301.

At S2032, the hard mask layer is etched back. The top of the hard mask layer is removed until the mandrel is exposed, and the side of the hard mask layer is retained as the side walls.

In the embodiments according to the semiconductor device of the disclosure, after depositing the hard mask layer 31, may etch back the hard mask layer 31, the top of the hard mask layer 31 is removed until the mandrel 301 is exposed, and the side of the hard mask layer 31 is retained as the side walls 311, as shown in FIG. 15A and FIG. 15B.

In some embodiments of the disclosure, S204 shown in FIG. 10 may be implemented through S2041 to S2042, which will be explained with reference to each operation.

At S2041, the mandrel between the side walls is removed.

In the embodiments of the disclosure, referring to FIG. 15A and FIG. 15B, the mandrel 301 remains between the side walls 311. Etching with a high selection etching ratio to remove the remaining mandrel 301 between the side walls 311, thereby obtaining the structure shown in FIG. 16A and FIG. 16B.

At S2042, the first blocking layer is etched by taking the side wall as a mask to form the first intermediate structure.

In the embodiments according to the semiconductor device of the disclosure, after removing the remaining mandrel 301 between the side walls 311, the first blocking layer 20 can be etched by taking the side wall 311 as a mask to form the first intermediate structure 201 shown in FIG. 17A and FIG. 17B, and expose the first dielectric wall 11 and the second dielectric wall 12. As shown in FIG. 17A, the first intermediate structure 201 extends in the second direction Y, and the first dielectric wall 11 and the second dielectric wall 12 are exposed at the gap between first intermediate structures 201.

At S2043, the first dielectric wall and the second dielectric wall are etched according to an etching rate ratio by taking the first intermediate structure as a mask, so as to form the groove.

In the embodiments according to the semiconductor device of the disclosure, after forming the first intermediate structure 201 shown in FIG. 17B, the first dielectric wall 11 and the second dielectric wall 12 can be etched according to an etching rate ratio by taking the first intermediate structure 201 as the mask, so as to form the groove 13 shown in FIG. 3A and FIG. 3B. In the groove 13, the height of the remaining first dielectric wall 11 is greater than the height of the remaining second dielectric wall 12.

In some embodiments of the disclosure, the etching rate ratio in S2043 includes the ratio of the etching rate of the material of the first dielectric wall to the etching rate of the material of the second dielectric wall, which is 1:4. Correspondingly, etching is performed according to the etching rate ratio of 1:4, and the height of the remaining first dielectric wall 11 in the groove 13 accounts for three fourths of the depth of the groove 13.

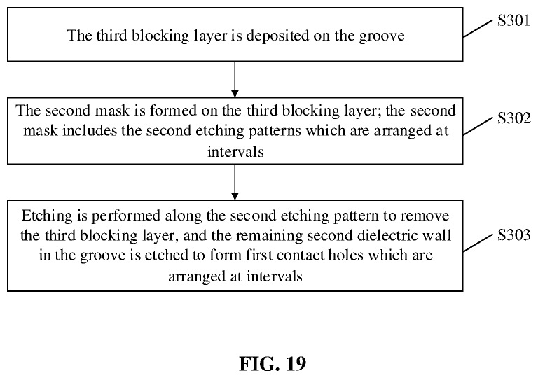

In some embodiments of the disclosure, S104 shown in FIG. 1 may be implemented through S301 to S303 shown in FIG. 19, which will be explained with reference to each operation.

At S301, the third blocking layer is deposited on the groove.

In the embodiments according to the semiconductor device of the disclosure, after forming the groove, a third blocking layer may be deposited on the groove to cover the groove. FIG. 20A and FIG. 20B are top and front sectional views respectively. As shown in FIG. 20A and FIG. 20B, the third blocking layer 50 is deposited on the groove 13 and covers the groove 13.

At S302, the second mask is formed on the third blocking layer. The second mask includes the second etching patterns which are arranged at intervals.

In the embodiments according to the semiconductor device of the disclosure, continuously referring to FIG. 20A and FIG. 20B, the second mask 60 may be formed on the third blocking layer 50 through the photolithography process. The second mask 60 includes the second etching patterns 601 which are arranged at intervals.

In the embodiments of the disclosure, the second etching pattern 601 is the concave hole on the second mask 60. The concave hole needs to be aligned with the square hole of the remaining second dielectric wall 12 in the groove 13. In this way, the first contact hole 14 may be formed at the position of the remaining second dielectric wall 12, as shown in FIG. 4A.

At S303, etching is performed along the second etching patterns, the third blocking layer is removed, and the remaining second dielectric wall in the groove is etched to form first contact holes which are arranged at intervals.

In the embodiments according to the semiconductor device of the disclosure, etching is performed at least once along the second etching patterns, the third blocking layer is removed, and the remaining second dielectric wall in the groove is etched to form the first contact holes which are arranged at intervals.

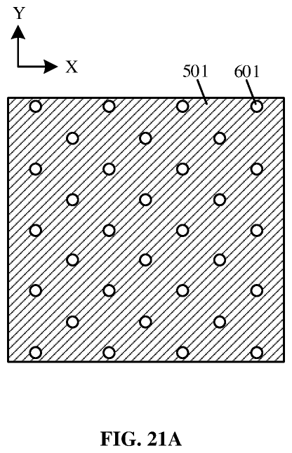

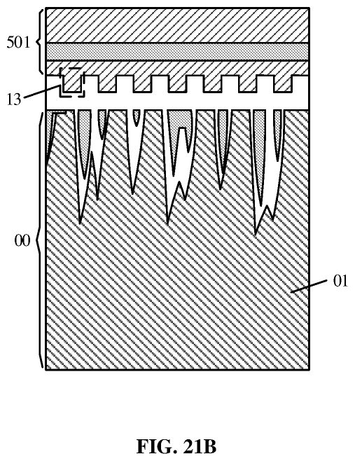

In the embodiments according to the semiconductor device of the disclosure, the third blocking layer 50 may be etched along the second etching patterns 601 to form a second intermediate structure 501 shown in FIG. 21A and FIG. 21B. The second etching pattern 601 is transferred to the second intermediate structure 501. Then, the remaining second dielectric wall 12 in the groove 13 may be etched by taking the second intermediate structure 501 as a mask to form the first contact hole 14 shown in FIG. 4A.

It is to be noted that the third blocking layer 50 may include a plurality of material layers, etching may be performed for a plurality of times at different etching rates selected according to different materials, thereby controlling the depth of the concave hole of the second etching pattern 601 on the second intermediate structure 501 and thus the depth of the obtained first contact hole 14. In this way, the active area 01 can be exposed at the position of the first contact hole 14. In other positions, the active area 01 is not exposed.

It is to be understood that corresponding to the position of the remaining second dielectric wall in the groove, the first contact holes which are arranged at intervals are formed by etching along the second etching pattern to expose the active area. In this way, the contact point with the active area is provided for the metal wiring only through once photomasking.

In some embodiments of the disclosure, S303 shown in FIG. 19 may be implemented through S3031 to S3032, which will be explained with reference to each operation.

At S3031, the third blocking layer is etched along the second etching patterns to form the second intermediate structure.

In the embodiments according to the semiconductor device of the disclosure, the third blocking layer 50 may be etched along the second etching pattern 601 to form the second intermediate structure 501 shown in FIG. 21A and FIG. 21B.

At S3032, the remaining second dielectric wall in the groove is etched by taking the second intermediate structure as a mask to form the first contact holes which are arranged at intervals.

In the embodiments according to the semiconductor device of the disclosure, the remaining second dielectric wall 12 in the groove 13 may be etched by taking the second intermediate structure 501 as a mask to form the first contact hole 14 shown in FIG. 4A.

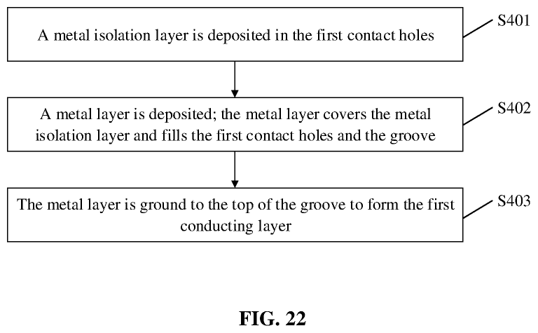

In some embodiments of the disclosure, S105 shown in FIG. 5 may be implemented through S401 to S403 shown in FIG. 22, which will be explained with reference to each operation.

At S401, the metal isolation layer is deposited in the first contact hole.

In the embodiments of the disclosure, referring to FIG. 4A, the first contact hole 14 exposes the active area 01, which may be used as the contact point between the metal layer and the active area 01. Before filling the first contact hole with the metal layer, the metal isolation layer needs to be deposited in the first contact hole. The metal isolation layer partially fills the first contact hole 14, and covers the exposed active area 01. The material of the metal isolation layer may be titanium nitride (TiN), which can prevent the metal material diffusing into the active area.

At S402, the metal layer is deposited. The metal layer covers the metal isolation layer and fills the first contact hole and the groove.

In the embodiments according to the semiconductor device of the disclosure, after depositing the metal isolation layer, the metal layer may be deposited. FIG. 23 is a front sectional view. As shown in FIG. 23, the metal layer 70 covers the metal isolation layer and fills the first contact hole 14 (not shown due to shielding) and the groove 13. The material of the metal layer 70 may be tungsten (W) or copper (Cu).

At S403, the metal layer is ground to the top of the groove, so that the first conducting layer is formed.

In the embodiments according to the semiconductor device of the disclosure, after depositing the metal layer 70, the metal layer 70 may be ground to the top of the groove 13, that is, the metal layer 70 is ground by the Damascus process to form the first conducting layer 15 shown in FIG. 24A and FIG. 24B.

In the embodiments of the disclosure, the first conducting layer 15 may be configured to the bit line structure.

It is to be understood that the first conducting layer is formed in the groove and is in contact with the active area through the first contact hole, so that the embedded bit line structure is formed, the height of the semiconductor structure is reduced, and the integration density in the vertical direction is improved.

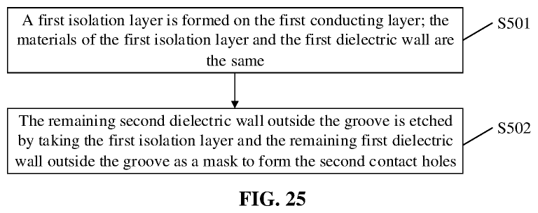

In some embodiments of the disclosure, S106 shown in FIG. 5 may be implemented through S501 to S502 shown in FIG. 25, which will be explained with reference to each operation.

At S501, the first isolation layer is formed on the first conducting layer. The materials of the first isolation layer and the first dielectric wall are the same.

In the embodiments according to the semiconductor device of the disclosure, the first isolation layer may be formed on the first conducting layer. The materials of the first isolation layer and the first dielectric wall are the same.

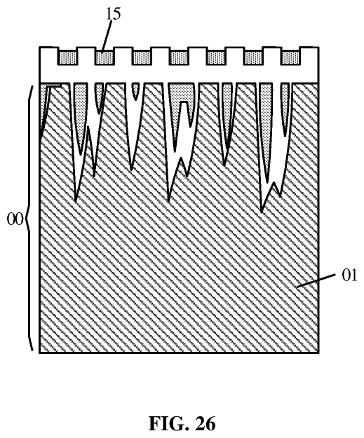

In the embodiments according to the semiconductor device of the disclosure, referring to FIG. 24B and FIG. 26, the first conducting layer 15 may be etched with a high selection ratio etching rate to reduce the height of the first conducting layer. The high selection ratio means that the etching rate of the material of the first conducting layer 15 is much higher than that of other materials.

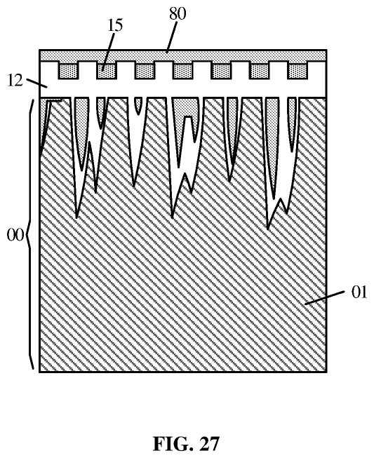

Then, as shown in FIG. 27, a fourth blocking layer 80 may be deposited on the first conducting layer 15. The fourth blocking layer 80 covers the remaining second dielectric wall 12 outside the groove.

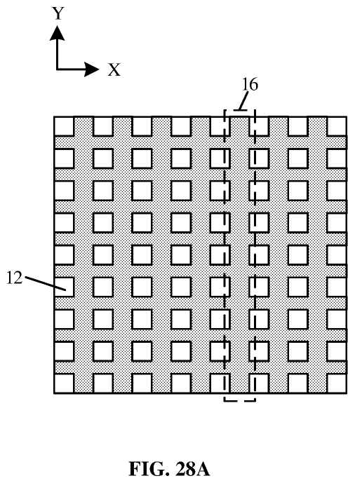

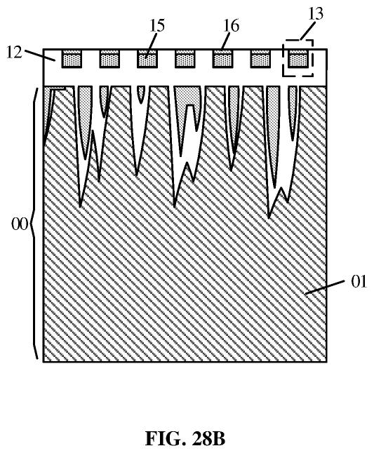

Then, as shown in FIG. 28A and FIG. 28B, the fourth blocking layer 80 may be ground until the remaining second dielectric wall 12 outside the groove is exposed, and the remaining fourth blocking layer 80 forms the first isolation layer 16.

At S502, the remaining second dielectric wall outside the groove is etched by taking the first isolation layer and the remaining first dielectric wall outside the groove as a mask to form the second contact hole.

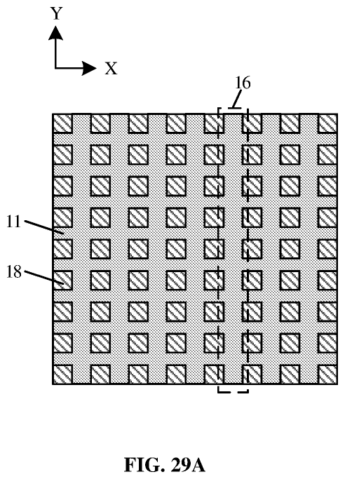

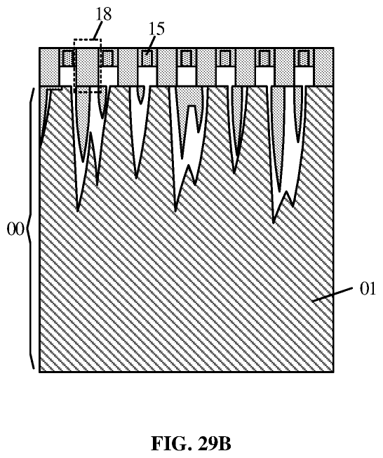

In the embodiments according to the semiconductor device of the disclosure, combined with FIG. 28A, FIG. 28B, FIG. 29A and FIG. 29B, due to the fact that the materials of the first isolation layer 16 and the first dielectric wall 11 are the same, the remaining second dielectric wall 12 outside the groove may be etched by taking the first isolation layer 16 and the remaining first dielectric wall 11 outside the groove as a mask to form the second contact hole 18 at the position of the second dielectric wall 12. The second contact hole 18 exposes the active area 01.

It is to be understood that the remaining second dielectric wall outside the groove is taken as a photomask, the second contact hole is formed in the corresponding position through etching, and the second conducting layer fills the second contact hole. In this way, the second contact hole is etched by utilizing the pattern of the semiconductor structure without a photomask, thereby achieving self-alignment. Meanwhile, the second conducting layer is of an embedded structure, so that the height of the semiconductor structure is reduced, and the integration density in the vertical direction is improved.

In some embodiments of the disclosure, S501 shown in FIG. 25 may be implemented through S5011 to S5013, which will be explained with reference to each operation.

At S5011, the first conducting layer is etched to reduce the height of the first conducting layer.

In the embodiments according to the semiconductor device of the disclosure, referring to FIG. 24B and FIG. 26, the first conducting layer 15 may be etched with high selection ratio etching rate to reduce the height of the first conducting layer.

At S5012, the fourth blocking layer is deposited on the first conducting layer. The fourth blocking layer covers the remaining second dielectric wall outside the groove.

In the embodiments according to the semiconductor device of the disclosure, as shown in FIG. 27, the fourth blocking layer 80 may be deposited on the first conducting layer 15. The fourth blocking layer 80 covers the remaining second dielectric wall 12 outside the groove.

At S5013, the fourth blocking layer is ground until the remaining second dielectric wall outside the groove is exposed, and the remaining fourth blocking layer forms the first isolation layer 16.

In the embodiments according to the semiconductor device of the disclosure, as shown in FIG. 28A and FIG. 28B, the fourth blocking layer 80 may be ground until the remaining second dielectric wall 12 outside the groove is exposed, and the remaining fourth blocking layer 80 forms the first isolation layer 16.

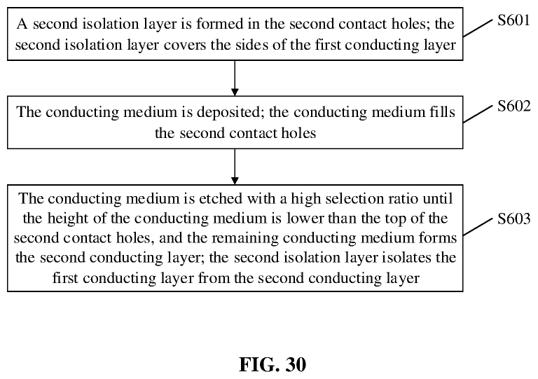

In some embodiments of the disclosure, S107 shown in FIG. 5 may be implemented through S601 to S603 shown in FIG. 30, which will be explained with reference to each operation.

At S601, the second isolation layer is formed in the second contact hole. The second isolation layer covers sides of the first conducting layer.

In the embodiments according to the semiconductor device of the disclosure, the second isolation layer may be formed in the second contact hole. FIG. 31B is a front sectional view. As shown in FIG. 31B, the second isolation layer 17 covers the sides of the first conducting layer 15. The materials of the second isolation layer 17 and the first dielectric wall 11 are the same.

At S602, the conducting medium is deposited. The conducting medium fills the second contact hole.

In the embodiments according to the semiconductor device of the disclosure, after forming the second isolation layer, the conducting medium may be deposited. FIG. 31A and FIG. 31B are top and front sectional views respectively. As shown in FIG. 31A and FIG. 31B, the conducting medium 90 fills the second contact hole 18 and covers the first conducting layer 15. The second isolation layer 17 isolates the conducting medium 90 from the first conducting layer 15. The material of the conducting medium 90 may be polycrystalline silicon.

At S603, the conducting medium is etched with a high selection ratio until the height of the conducting medium is lower than the top of the second contact hole. The remaining conducting medium forms the second conducting layer. The second isolation layer isolates the first conducting layer from the second conducting layer.

In the embodiments of the disclosure, FIG. 32A and FIG. 32B are top and front sectional views respectively. Combined with FIG. 31A, FIG. 31B, FIG. 32A and FIG. 32B, after depositing the conducting medium 90, the conducting medium 90 may be etched with a high selection ratio, that is, the etching rate of the conducting medium 90 is higher than that of other materials. Etching is performed until the height of the conducting medium 90 is lower than the top of the second contact hole 18, thereby exposing the remaining first dielectric wall 11 and first isolation layer 16 outside the groove, as shown in FIG. 32A. In this way, the remaining conducting medium 90 forms the second conducting layer 19. The second isolation layer 17 isolates the first conducting layer 15 from the second conducting layer 19.

It is to be understood that the same material as the first dielectric wall 11 is selected to form the second isolation layer 17 on sides of the first conducting layer 15. In this way, the proper etching selection ratio may be selected by utilizing material characteristics to etch the conducting medium 90, so that the first dielectric wall 11 and the second isolation layer 17 are retained. At the same time, the second isolation layer 17 isolates the first conducting layer 15 from the second conducting layer 19, thereby avoiding a short circuit.

The embodiments of the disclosure further provide a semiconductor structure 08, which is prepared by the preparation method provided by the above embodiments.

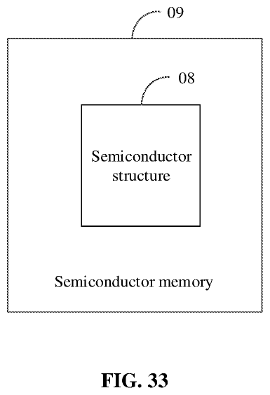

The embodiments of the disclosure further provide a semiconductor memory 09, which at least includes the semiconductor structure 08, as shown in FIG. 33.

In some embodiments of the disclosure, the semiconductor memory 09 shown in FIG. 33 at least includes the DRAM.

It is to be noted that the terms “include”, “contain” or any other variations thereof in the present disclosure are intended to cover a non-exclusive inclusion, such that a process, method, article or equipment including a series of elements not only includes those elements, but also includes those elements that are not explicitly listed, or includes elements inherent to such a process, method, article or device. Under the condition of no more limitations, it is not excluded that additional identical elements further exist in the process, method, article or device including elements defined by a sentence “including a . . . ”.

The serial numbers of the embodiments of the disclosure are merely for description and do not represent a preference of the embodiments. The methods disclosed in several method embodiments provided in the present disclosure may be arbitrarily combined without conflict to obtain a new method embodiment. The characteristics disclosed in several product embodiments provided in the present disclosure may be arbitrarily combined without conflict to obtain a new product embodiment. The characteristics disclosed in the several method or device embodiments provided in the present disclosure may be arbitrarily combined without conflict to obtain a new method embodiments or device embodiment.

The above is only the specific implementation mode of the present disclosure and not intended to limit the scope of protection of the present disclosure. Any variations or replacements apparent to those skilled in the art within the technical scope disclosed by the disclosure shall fall within the scope of protection of the present disclosure. Therefore, the scope of protection of the present disclosure shall be subjected to the scope of protection of the claims.

What is claimed is:

1. A method for preparing a semiconductor structure, comprising:
providing a substrate, an active area being comprised in the substrate;
forming a first dielectric wall and a second dielectric wall extending in a first direction on the substrate, the first dielectric wall and the second dielectric wall being alternately distributed;
etching the first dielectric wall and the second dielectric wall to form a groove extending in a second direction, wherein grooves are arranged at intervals, and in the groove, a height of a remaining first dielectric wall is greater than a height of a remaining second dielectric wall; and
etching the remaining second dielectric wall in the groove to form first contact holes which are arranged at intervals in the groove, the first contact holes exposing the active area.

2. The method of claim 1, wherein after the etching the remaining second dielectric wall in the groove to form first contact holes which are arranged at intervals in the groove, the method further comprises:
forming a first conducting layer in the groove, the first conducting layer filling the first contact holes and filling at least part of the groove;
etching the remaining second dielectric wall outside the groove to form second contact holes, the second contact holes exposing the active area; and
forming a second conducting layer in the second contact holes.

3. The method of claim 1, wherein the etching the first dielectric wall and the second dielectric wall to form a groove extending in a second direction comprises:
depositing a first blocking layer and a second blocking layer on the first dielectric wall and the second dielectric wall in sequence;
etching the second blocking layer to form mandrels extending in the second direction, the mandrels being arranged at intervals;
forming side walls by covering sides of the mandrels; and
performing etching by taking the side walls as a mask to remove the first blocking layer, and etching the first dielectric wall and the second dielectric wall to form the groove.

4. The method of claim 3, wherein the etching the second blocking layer to form mandrels extending in the second direction comprises:
forming a first mask on the second blocking layer, the first mask comprising a first etching pattern extending in the second direction; and
etching the second blocking layer along the first etching pattern to form the mandrels extending in the second direction.

5. The method of claim 3, wherein the forming side walls by covering sides of the mandrels comprises:
depositing a hard mask layer, the hard mask layer covering the first blocking layer and the mandrels; and
etching back the hard mask layer to remove a top of the hard mask layer until the mandrels are exposed and retain sides of the hard mask layer as the side walls.

6. The method of claim 3, wherein the performing etching by taking the side walls as a mask to remove the first blocking layer, and etching the first dielectric wall and the second dielectric wall to form the groove comprises:
removing the mandrels between the side walls;
etching the first blocking layer by taking the side walls as the mask to form a first intermediate structure; and
etching the first dielectric wall and the second dielectric wall according to an etching rate ratio by taking the first intermediate structure as a mask, so as to form the groove.

7. The method of claim 6, wherein the etching rate ratio comprises a ratio of an etching rate of a material of the first dielectric wall to an etching rate of a material of the second dielectric wall, which is 1:4.

8. The method of claim 1, wherein the etching the remaining second dielectric wall in the groove to form first contact holes which are arranged at intervals in the groove comprises:
depositing a third blocking layer on the groove;
forming a second mask on the third blocking layer, the second mask comprising second etching patterns which are arranged at intervals; and
performing etching along the second etching patterns to remove the third blocking layer, and etching the remaining second dielectric wall in the groove to form the first contact holes which are arranged at intervals.

9. The method of claim 8, wherein the performing etching along the second etching patterns to remove the third blocking layer, and etching the remaining second dielectric wall in the groove to form the first contact holes which are arranged at intervals comprises:
etching the third blocking layer along the second etching patterns to form a second intermediate structure; and
etching the remaining second dielectric wall in the groove by taking the second intermediate structure as a mask to form the first contact holes which are arranged at intervals.

10. The method of claim 2, wherein the first conducting layer comprises a metal isolation layer and a metal layer; the forming a first conducting layer in the groove comprises:
depositing the metal isolation layer in the first contact holes;
depositing the metal layer, the metal layer covering the metal isolation layer and filling the first contact holes and the groove; and
grinding the metal layer to a top of the groove to form the first conducting layer.

11. The method of claim 2, wherein the etching the remaining second dielectric wall outside the groove to form second contact holes comprises:
forming a first isolation layer on the first conducting layer, materials of the first isolation layer and the first dielectric wall being the same; and
etching the remaining second dielectric wall outside the groove by taking the first isolation layer and the remaining first dielectric wall outside the groove as a mask to form the second contact holes.

12. The method of claim 11, wherein the forming a first isolation layer on the first conducting layer comprises:
etching the first conducting layer to reduce a height of the first conducting layer;
depositing a fourth blocking layer on the first conducting layer, the fourth blocking layer covering the remaining second dielectric wall outside the groove; and
grinding the fourth blocking layer until the remaining second dielectric wall outside the groove is exposed, and a remaining fourth blocking layer forming the first isolation layer.

13. The method of claim 2, wherein the forming a second conducting layer in the second contact holes comprises:
forming a second isolation layer in the second contact holes, the second isolation layer covering sides of the first conducting layer;
depositing a conducting medium, the conducting medium filling the second contact holes; and
etching the conducting medium with a high selection ratio until a height of the conducting medium is lower than a top of the second contact holes, remaining conducting medium forming the second conducting layer, the second isolation layer isolating the first conducting layer from the second conducting layer.

14. A semiconductor structure, prepared by the method of claim 1.

15. A semiconductor memory, comprising the semiconductor structure of claim 14.

16. The semiconductor memory of claim 15, at least comprising: a Dynamic Random Access Memory (DRAM).
